(19) United States
(12) Patent Application Publication
(10) Pub. No.: US 2024/0183260 A1
(43) Pub. Date: Jun. 6, 2024

(54) VOLUME-BASED PROPPANT TRAPPING FOR MODIFYING FRACKING IN THE SUBSURFACE

(71) Applicant: ExxonMobil Technology and Engineering Company, Spring, TX (US)

(72) Inventors: Ripudaman MANCHANDA, Houston, TX (US); Holger A. MEIER, Montgomery, TX (US); Peeyush BHARGAVA, The Woodlands, TX (US)

(21) Appl. No.: 18/555,246

(22) PCT Filed: Feb. 4, 2022
(86) PCT No.: PCT/US2022/070521

§ 371 Date: Oct. 12, 2023

Related U.S. Application Data
(60) Provisional application No. 63/180,908, filed on Apr. 28, 2021.

(51) Int. Cl. E21B 43/267

(52) U.S. Cl. CPC E21B 43/267; E21B 2200/20

(57) ABSTRACT

A method and a system for volume-based proppant trapping along a fracture surface is disclosed. Hydraulic fracturing involves injecting proppant to ensure separation of the fracture surfaces after the stimulation treatment is completed. The spatial placement of proppant is assumed to be directly related to the fracture conductivity along the hydraulic fracture as well as its connectivity to the wellbore. Fracture conductivity is an important focus of designing fracture treatments since fracture conductivity may be directly related to the well performance. Thus, improving one or more aspects of proppant placement, such as determining the optimal type, size and/or concentration of proppant(s) may enhance fracture conductivity and in turn improve well performance. In order to understand the placement of proppant in the subsurface, a volume-based proppant trapping model is used. The volume-based proppant trapping model may factor in parameters associated with the subsurface, parameters associated with the proppants, and user parameters, such as the total volume of proppant along the fracture surface, thereby assisting in hydraulic fracturing.

### CROSS-REFERENCE TO RELATED APPLICATIONS

This application is the U.S. National Stage Application of the International Application No. PCT/US2022/070521, entitled “VOLUME-BASED PROPPANT TRAPPING FOR MODIFYING FRACKING IN THE SUBSURFACE,” filed on Feb. 4, 2022, the disclosure of which is hereby incorporated by reference in its entirety, which claims priority to and the benefit of U.S. Provisional Application No. 63/180,908, filed on Apr. 28, 2021, the entire contents of which are incorporated herein by reference.

### FIELD OF THE INVENTION

The present application relates generally to the field of hydrocarbon production. Specifically, the disclosure relates to a methodology for volume-based proppant trapping along a fracture surface for use in hydraulic fracturing.

### BACKGROUND OF THE INVENTION

This section is intended to introduce various aspects of the art, which may be associated with exemplary embodiments of the present disclosure. This discussion is believed to assist in providing a framework to facilitate a better understanding of particular aspects of the present disclosure. Accordingly, it should be understood that this section should be read in this light, and not necessarily as admissions of prior art.

Hydraulic fracturing (interchangeably termed fracking) has been widely used as an effective technique to improve well productivity by forming high permeable pathways for hydrocarbons to flow from the rock formation to the wellbore. The process of hydraulic fracturing involves pumping down fluids at a prescribed flow rate through the wellbore/casing and into the formation through perforations. When the fluid pressure exceeds the rock breakdown pressure, the fluid pressure creates a fracture in the formation. Proppants, such as sand, are pumped with fracturing fluid to keep the fracture open after release of pumping pressure. Example of hydraulic fracturing are disclosed in US Patent Application Publication No. 2020/0380186 A1 and US Patent Application Publication No. 2021/0047906 A1, both of which are incorporated by reference herein in their entirety.

Specifically, proppant may be injected during the process of hydraulic fracturing to ensure separation of the fracture surfaces after the stimulation treatment is completed. The spatial placement of proppant may be assumed to be directly related to the conductivity along the hydraulic fracture as well as its connectivity to the wellbore. Thus, proppant placement may be strongly related to the capability of effectively and economically producing hydrocarbons from the reservoir. Furthermore, propped fracture dimensions may be used to determine proper well spacing to optimize depletion.

To understand the placement of proppant in the subsurface, numerical models may be used which mimic proppant transport and proppant trapping along the fracture dimensions. The process of proppant trapping may encompass some or all mechanisms via which the injected proppant is retained along the fracture. Simulation of proppant trapping in fracking models may be based on proppant bridging or mass-based proppant trapping.

### SUMMARY OF THE INVENTION

In one or some embodiments, a computer-implemented method for using a volume-based proppant trapping model is disclosed. The method includes accessing one or more inputs; inputting the one or more inputs into the volume-based proppant trapping model in order to generate one or more outputs indicative of proppant trapping in or at a fracture surface; and outputting the one or more outputs or using the one or more outputs in order to control at least one aspect fracking in a subsurface.

### BRIEF DESCRIPTION OF THE DRAWINGS

The present application is further described in the detailed description which follows, in reference to the noted plurality of drawings by way of non-limiting examples of exemplary implementations, in which like reference numerals represent similar parts throughout the several views of the drawings. In this regard, the appended drawings illustrate only exemplary implementations and are therefore not to be considered limiting of scope, for the disclosure may admit to other equally effective embodiments and applications.

FIG. 1 illustrates a diagram of a wellbore, perforations, and fractures.

FIG. 2 is a block diagram of the fracking simulator system and database.

FIG. 3 is an example flow diagram for generating and using a volume-based proppant trapping model.

FIG. 4 is an illustration of a grid of the surface of a fracture and associated calculations related to proppant in a section of the grid.

FIGS. 5A-D are schematics illustrating differences in the mass-based proppant trapping approach versus the volume-based proppant trapping approach for a regular proppant density distribution and a lower-proppant density distribution.

FIG. 6 is a diagram of an exemplary computer system that may be utilized to implement the methods described herein.

### DETAILED DESCRIPTION OF THE INVENTION

The methods, devices, systems, and other features discussed below may be embodied in a number of different forms. Not all of the depicted components may be required, however, and some implementations may include additional, different, or fewer components from those expressly described in this disclosure. Variations in the arrangement and type of the components may be made without departing from the spirit or scope of the claims as set forth herein. Further, variations in the processes described, including the addition, deletion, or rearranging and order of logical operations, may be made without departing from the spirit or scope of the claims as set forth herein.

It is to be understood that the present disclosure is not limited to particular devices or methods, which may, of course, vary. It is also to be understood that the terminology used herein is for the purpose of describing particular embodiments only, and is not intended to be limiting. As used herein, the singular forms “a,” “an,” and “the” include singular and plural referents unless the content clearly dictates otherwise. Furthermore, the words “can” and “may” are used throughout this application in a permissive sense (i.e., having the potential to, being able to), not in a mandatory sense (i.e., must). The term “include,” and derivations thereof, mean “including, but not limited to.” The term “coupled” means directly or indirectly connected. The word “exemplary” is used herein to mean “serving as an example, instance, or illustration.” Any aspect described herein as “exemplary” is not necessarily to be construed as preferred or advantageous over other aspects. The term “uniform” means substantially equal for each sub-element, within about ±10% variation.

As used herein, “hydrocarbon management” or “managing hydrocarbons” includes any one, any combination, or all of the following: hydrocarbon extraction; hydrocarbon production, (e.g., drilling a well and prospecting for, and/or producing, hydrocarbons using the well; and/or, causing a well to be drilled, e.g., to prospect for hydrocarbons); hydrocarbon exploration; identifying potential hydrocarbon-bearing formations; characterizing hydrocarbon-bearing formations; identifying well locations; determining well injection rates; determining well extraction rates; identifying reservoir connectivity; acquiring, disposing of, and/or abandoning hydrocarbon resources; reviewing prior hydrocarbon management decisions; and any other hydrocarbon-related acts or activities, such activities typically taking place with respect to a subsurface formation. The aforementioned broadly include not only the acts themselves (e.g., extraction, production, drilling a well, etc.), but also or instead the direction and/or causation of such acts (e.g., causing hydrocarbons to be extracted, causing hydrocarbons to be produced, causing a well to be drilled, causing the prospecting of hydrocarbons, etc.). Hydrocarbon management may include reservoir surveillance and/or geophysical optimization. For example, reservoir surveillance data may include, well production rates (how much water, oil, or gas is extracted over time), well injection rates (how much water or CO₂ is injected over time), well pressure history, and time-lapse geophysical data. As another example, geophysical optimization may include a variety of methods geared to find an optimum model (and/or a series of models which orbit the optimum model) that is consistent with observed/measured geophysical data and geologic experience, process, and/or observation.

As used herein, “obtaining” data generally refers to any method or combination of methods of acquiring, collecting, or accessing data, including, for example, directly measuring or sensing a physical property, receiving transmitted data, selecting data from a group of physical sensors, identifying data in a data record, and retrieving data from one or more data libraries.

As used herein, terms such as “continual” and “continuous” generally refer to processes which occur repeatedly over time independent of an external trigger to instigate subsequent repetitions. In some instances, continual processes may repeat in real time, having minimal periods of inactivity between repetitions. In some instances, periods of inactivity may be inherent in the continual process.

If there is any conflict in the usages of a word or term in this specification and one or more patent or other documents that may be incorporated herein by reference, the definitions that are consistent with this specification should be adopted for the purposes of understanding this disclosure.

As discussed in the background, the spatial placement of proppant may be assumed to be related to the fracture conductivity along the hydraulic fracture as well as its connectivity to the wellbore. Fracture conductivity is an important focus of designing fracture treatments since fracture conductivity may be directly related to the well performance. Typically, the region where the proppant is trapped has higher conductivity; conversely, the region where the proppant is not trapped has lower conductivity. Thus, it is advisable to increase the region of fracture where the proppant is trapped. In this regard, proppant trapping may be simulated in fracking models using proppant bridging or mass-based proppant trapping criterion, which in turn, may be used to improve well performance, such as improving fracture conductivity. However, proppant bridging may not be sufficient to capture the effect of reservoir and fracture heterogeneities. Similarly, mass-based proppant trapping mechanisms, which are focused on allowing a maximum mass of the proppant mixture to trap along the surface of the fracture, may under certain circumstances yield unphysical outcomes. For example, for the same maximum mass of trapped proppant in two separate scenarios, one with low density proppant and another with high density proppant, would result in a much larger volume of the low density proppant than the high density proppant being trapped. Furthermore, using a mixture of low and high density proppant would result in a disproportionately larger volume of the low density proppant to be trapped along the fracture surface in fracking modeling simulations.

Thus, in one or some embodiments, a volume-based proppant trapping model is used in fracking simulations in order to model proppant trapping. As opposed to the mass-based proppant approach, the volume-based proppant trapping model may improve or rectify proppant trapping calculations in scenarios where proppants of different densities are considered. In particular, the volume-based trapping criterion, upon which the volume-based proppant trapping model may be based, may enable equivalent volume of low and high density proppants being trapped.

Various aspects may be analyzed for trapping of the proppant along the fracture (e.g., the fracture surface). In particular, the volume-based proppant trapping model may depend on a variety of parameters, such as any one, any combination, or all of: parameter(s) associated with the subsurface; parameter(s) associated with proppant(s); or user parameters. For example, the parameters may comprise any one, any combination, or all of: rock properties; fluid properties; proppant(s) properties; heterogeneity; trapping rate; user defined properties; etc. In particular, one user-defined property comprises the maximum allowed trapped volume of all proppant types per unit fracture surface area V_{tot,max}. As discussed in more detail below, V_{tot,max} may serve as a constraint for interpreting and solving the model. Another user-defined property comprises the volume of proppant that is passed along the fracture surface Vₚₐₛₛ, such as flowing volume of proppant in the fracture. Similarly, Vₚₐₛₛ may serve as a constraint for interpreting and solving the model. Other constraints are contemplated. Further, other manners in which to interpret the model, separate from or in addition to constraints, are contemplated.

Further, properties of the volume-based proppant trapping model may be any combination of constant or variable. In particular, any one, any combination, or all of the properties of the volume-based proppant trapping model may be considered constant along the entirety of the fracture surface, may be considered spatially dependent entirely along the fracture surface, or may be constant along a part of the fracture surface and variable along a remaining part of the fracture surface.

With regard to variability, one or more properties of the volume-based proppant trapping model may be variable based on any one, any combination, or all of: time dependence (e.g., based on a current time); spatial dependence (e.g., spatially dependent along one, some, or each of the x, y, or z axes); type of proppant dependence; or sequence of introduction of proppants dependence (e.g., a sequence in which proppants are introduced). As one example, with regard to spatial dependence, any one, any combination, or all of the properties of the volume-based proppant trapping model may be considered constant along the fracture surface, may be considered spatially dependent along the fracture surface, or may be constant along a part of the fracture surface and variable along a remaining part of the fracture surface. As another example, with regard to sequence dependent, trapping of the proppant may be dependent on the sequence in which the proppants are introduced and/or dependent on the percentages of proppants introduced. In particular, the proppants may be introduced in a certain sequence such that at time t=t₁, a first amount of proppant was trapped, at t=t₂, a second amount of proppant was trapped, at t=t₃, a third amount of proppant was trapped, etc. In this way, the sequence may indicate a history of trapping of proppant.

Merely by way of example, V_{tot,max} may be represented as time dependent, spatially dependent, sequence dependent, proppant dependent (e.g., V_{i,tot,max} represents a total trapped volume for one, some, or each proppant (i); alternatively, V_{tot,max} represents a total trapped volume for all proppants) as follows:

V_{i,tot,max}(x,y,z)=F(t,s,x,y,z,rock prop(x,y,z),fluid properties,proppant properties,heterogeneity(x,y,z), . . . .) (1).

Equation (1) may be modified in any combination based on the different dependencies, as discussed above. Similarly, the volume of proppant passed along the fracture surface may include the same dependence as listed above for V_{tot,max}, such as any one, any combination, or all of time dependent, spatially dependent, sequence dependent, proppant dependent.

Alternatively, or in addition, the parameter(s) may be proppant dependent. Merely by way of example, V_{i,trap} may be represented as time dependent, spatially dependent, sequence dependent, and proppant dependent as follows:

V_{i,trap}(t,x,y,z)=f(t,x,y,z,rock prop(x,y,z),fluid properties,proppant properties,heterogeneity(x,y,z),V_{j,trap} . . . .) (2)

where i indicates a first type of proppant and j indicates a first type of proppant and where s indicates a sequence. As shown in Equation (2), V_{i,trap} may also depend on V_{j,trap} (and vice versa).

In this regard, any properties (interchangeably termed parameters) may be any combination of spatially dependent, spatially independent, proppant-type dependent, or proppant-type independent.

In this way, the manifestation of the volume-based proppant trapping model may take one of many forms. One form to define the volume-based proppant trapping methodology, with parameters being spatially constant, is by using the following set of equations:

$$\frac{d {V}_{i , trap}}{d L} = {K}_{trap} ( {V}_{i} - {V}_{i , trap} ) \qquad ( 3 )$$

where V_{i,trap} is volume of trapped proppant for proppant type i per unit fracture surface area;
where Kₜᵣₐₚ is a rate constant (1/min);
where Vᵢ is the volume of proppant type i per unit fracture surface area; and
where V_{tot,max} is the maximum allowed trapped volume of all proppant types per unit fracture surface area. As discussed in more detail below, for multiple proppant types used, the various V_{i,trap} may be summed so that

$$Σ {V}_{i , trap} \leq {V}_{tot , max}$$

(e.g., for two proppant types, V_{1,trap}+V_{2,trap}≤V_{tot,max}).

As discussed above, alternatively, or in addition, the volumetric proppant trapping methodology may use the volume of proppant that is passed along the fracture surface Vₚₐₛₛ. such as flowing volume of proppant in the fracture.

As shown above, the volumetric proppant trapping methodology of proppant is defined by using values for V_{tot,max} and Kₜᵣₐₚ. See Equation (3). Alternatively, as discussed above, the volume-based proppant trapping model may be based on any one, any combination, or all of: rock-based parameters (e.g., rock properties, such as lithology, mechanical, flow, geology, roughness, etc.); proppant-based parameters; operational parameters (flow rate, proppant concentration, etc.); or fluid parameters (e.g., fluid rheology, etc.).

Further, as discussed above, one or both of V_{tot,max} and Kₜᵣₐₚ are predetermined and non-variant. For example, V_{tot,max} may be predetermined and static. Alternatively, one or both of V_{tot,max} and Kₜᵣₐₚ may vary, such as based on specific circumstances or based on a focus for optimization. In particular, in certain instances, the value for V_{tot,max} may be static, with the focus of the simulation determining other aspects of operation, such as the type(s)/concentration(s) of proppants and/or the timing/scheduling of introducing proppant(s) into the system.

Alternatively, or in addition, one or both of V_{tot,max} and Kₜᵣₐₚ may be dependent on one or more factors related to specific circumstances. As one example, the value for V_{tot,max} may vary and be the subject of the simulation (e.g., how much total proppant to introduce into the system). As another example, one or both of V_{tot,max} and Kₜᵣₐₚ may be dependent on one or both of: specific circumstances regarding the subsurface, such as rock properties (e.g., any one, any combination, or all of lithology, mechanical, flow, geology, or roughness); or specific circumstances such as the proppant type(s) available for fracking, or specific circumstances such as the kind of fluid available used for fracking (e.g., fluid rheology). For example, V_{i,tot,max} and K_{i,trap} may be specific to each proppant type i injected. As another example, V_{r,tot,max} and K_{r,trap} may be specific to each rock type at the fracture (with r designated for rock type r).

Further, any one of the parameters for the volume-based proppant trapping model, such as one or both of the spatially dependent maximum allowed trapped volume of proppant along the fracture surface or a spatially dependent rate of trapping may be randomly distributed along the fracture surface. Various statistical methodologies may be used to generate the random distribution. In this way, ranges and or distributions associated with various parameters for the volume-based proppant trapping model may be defined, such as randomly.

Regardless, the volume-based proppant trapping model may be dependent on a variety of parameters, including parameter(s) associated with the subsurface; parameter(s) associated with proppant(s); or user parameters. Other formulations of the volumetric proppant trapping mechanism are contemplated. In this regard, the volume-based proppant trapped model may be based on formulations other than described above with regard to Equation (3).

Thus, in determining a solution regarding the volume-based proppant trapping model, various combinations of the parameters may be investigated in order to determine a better or optimal solution, thereby improving operations in a variety of contexts in which the volume-based proppant trapping model may be used. In particular, improving or optimizing one or more aspects of proppant placement, such as determining the optimal type, size and/or concentration of proppant(s) may enhance fracture conductivity and in turn improve well performance. In one example, the volume-based proppant trapping model may be used to assess well spacing and completions design impact on well productivity. In particular, the methodology may be used in hydraulic fracturing simulators to enable accurate characterization of proppant trapping in a hydraulic fracture in scenarios where the various proppants injected have different densities. This may, in turn, enable better quantification of the propped surface area of the fracture and help in improving the calculated impact of a completion design on well productivity. Enhancing the ability to accurately simulate well productivity plays into various well spacing and completion design questions, which may help guide decision making and increase profitability.

In another example, the volume-based proppant trapping model may be used for one or both of selection of the different types of proppants or the treatment schedule for the different types of proppants. In particular, the volume-based proppant trapping model may be used to optimize treatment design and proppant sequencing of different types. In this regard, accurately modeling of proppant trapping may help in optimizing the proppant schedule to maximize well productivity while reducing or minimizing the volume of proppant injected. Alternatively, the volume-based proppant trapping model may be used for simulation of different types of proppants, such as proppants of different densities. Thus, as discussed in more detail below, the volume-based proppant trapping model may be used to determine any one, any combination, or all of: what types of proppant to use in a particular well (e.g., low density versus high density); when to inject which proppant (e.g., inject lower density before higher density or vice versa); what percentage of each type of proppant to inject; what sequence to use in injecting the proppants (e.g., cycle the different proppants or have fillers in between); or what concentration ramps to use for different proppant types (e.g., the concentration of proppant may be ramped, such as upward or downward).

In still another example, the volume-based proppant trapping model may be used for field diagnostic consistent fracking modeling. More specifically, certain field diagnostic methods may help in constraining the propped dimensions of a fracture. Proppant transport modeled in fracking simulators may be used to match these diagnostic observations. Accurate representation of proppant trapping may improve the ability of the fracking model to be used in forecasting scenarios.

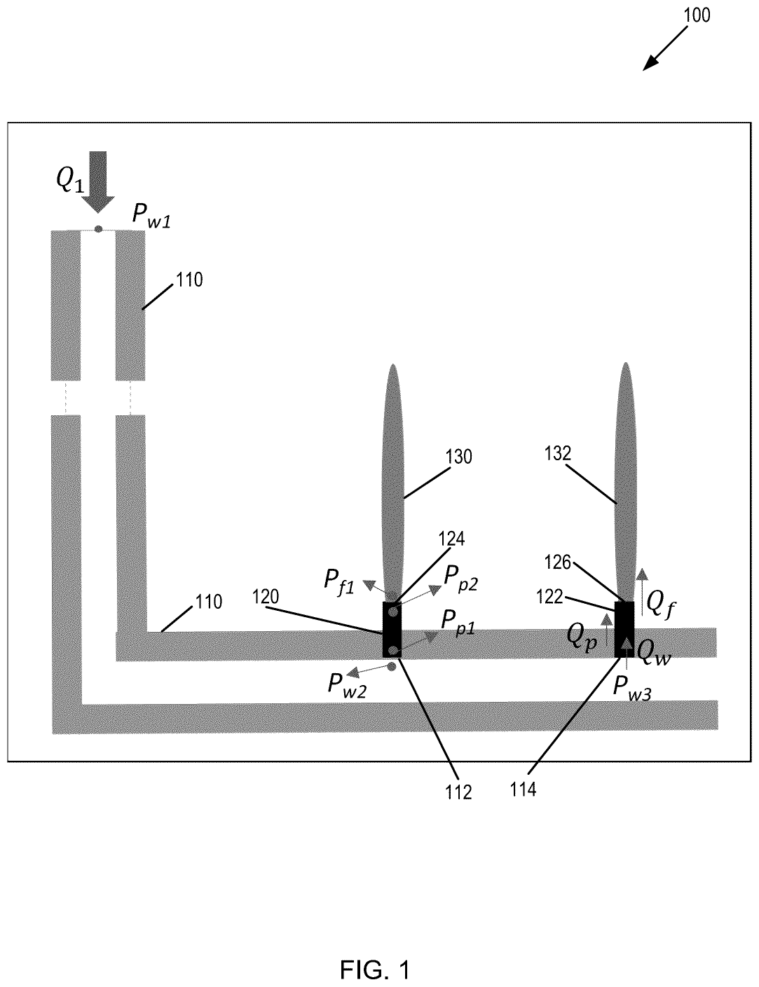

Referring to the figures, FIG. 1 illustrates a diagram 100 of a wellbore 110, perforations 120, 122, and fractures 130, 132. FIG. 1 is one example of fracturing in a subsurface. Other examples are contemplated. As shown, an entry into wellbore 110 includes flow rate (e.g., mass flow rate) of fluid Q1 and pressure Pw1. Wellbore 110 includes a casing so that there are a finite number of perforations, shown as perforation 120, 122. Alternatively, wellbore 110 may not include a casing. Further, there is a first wellbore-perforation interface 112 between wellbore 110 and perforation 120, and a second wellbore-perforation interface 114 between wellbore 110 and perforation 122. At the first wellbore-perforation interface 112, pressure on the wellbore side (Pw2) equals pressure on the perforation side (Pp1). Likewise, fluid flow is illustrated in FIG. 1, including fluid flow on the wellbore side into perforation 122 (Qw), fluid flow through perforation 122 (Qp), and fluid flow through fracture 132 (Qf). Similar to pressure at the interfaces, at the second wellbore-perforation interface 114, fluid flow out of the wellbore side into the perforation equals fluid flow into the perforation side. As discussed further below, the respective components for a respective interface may be set equal to one another in order to determine the fluid flow at the respective interface.

FIG. 1 further illustrates first perforation-fracture interface 124, in which pressure on the perforation side (Pp2) equals pressure on the fracture side (Pf1), and second perforation-fracture interface 126. Further, fluid flow exiting the perforation side into second perforation-fracture interface 126 equals fluid flow on the fracture side out of second perforation-fracture interface 126.

Further, one, some, or each of the wellbores may have respective perforations through a well casing. A fracturing fluid may be pumped at high pressure through the perforations. When the pressure of the fluid exceeds the strength of the rock layer, fractures will form as the rock breaks. The fracturing fluid may be aqueous or non-aqueous, and may contain materials to hold open the fractures that form. As discussed above, these materials, known as proppants, may include natural or synthetic materials such as sand, gravel, ground shells, glass beads, or metal beads, among others.

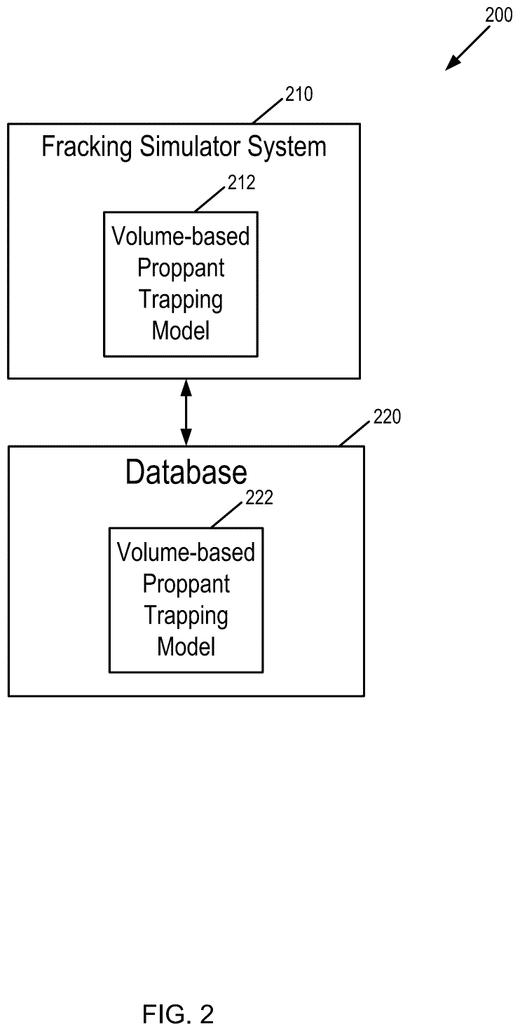

FIG. 2 is a block diagram 200 of the fracking simulator system 210 and database 220. Though FIG. 2 illustrates database 220 as separate from the fracking simulator system 210, database 220 may be integrated within simulator system 210. In one implementation, fracking simulator system 210 includes a volume-based proppant trapping model 212. As discussed above, the volume-based proppant trapping model 212 may be based on one or more equations, such as based on Equation (3) discussed above. Further, database 220 may include simulation values 222 for one or more inputs to the volume-based proppant trapping model 212, such as V_{tot,max} and Kₜᵣₐₚ. In practice, the volume-based proppant trapping model 212 may be called as part of an overall fracking simulation performed by fracking simulator system 210. For example, the volume-based proppant trapping model 212 may be used for one or more applications related to fracking, which may include simulations regarding well spacing and completions design impact on well productivity or regarding proppant trapping in a hydraulic fracture in scenarios where the various proppants injected have different densities and/or different concentrations.

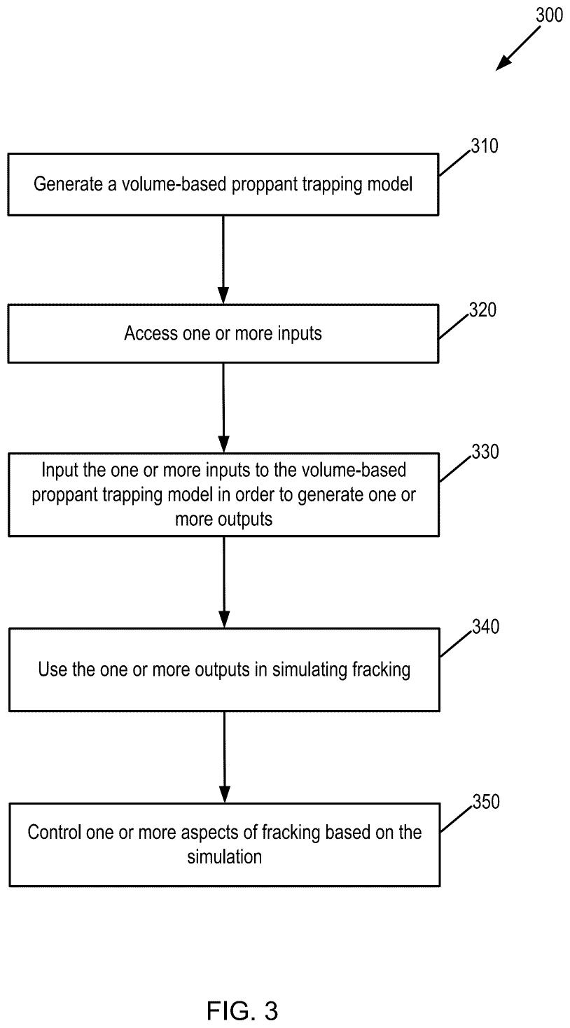

FIG. 3 is an example flow diagram 300 for generating and using a volume-based proppant trapping model. At 310, a volume-based proppant trapping model is generated. As discussed above, the volume-based proppant trapping model may be manifested in one of several ways, such as using the equations discussed above. At 320, one or more inputs are accessed. At 330, the inputs may be input to the volume-based proppant trapping model to generate one or more outputs. At 340, the one or more outputs may be used in simulating fracking. As discussed above, various inputs, including V_{tot,max} and Kₜᵣₐₚ, may be used by the volume-based proppant trapping model to generate the one or more outputs. Thus, the output(s) of the volume-based proppant trapping model may be used as part of another simulation. For example, a fracking simulation may determine one or more aspects of fracking, such as fracture conductivity. In turn, the one or more aspects of fracking determined by the simulation, such as the fracture conductivity, may in turn be input to another simulator, such as a reservoir simulator. Alternatively, or in addition, the one or more outputs may be output, such as on a display. In turn, the simulation may be used in order to control one or more aspects of fracking. Merely by way of example, data (such as diagnostics data) may be sensed in a particular subsurface responsive to performing fracking. The data may be analyzed, such as via the volume-based proppant trapping model and simulations, in order to at 350 control, modify, improve, or optimize one or more aspects for fracking (e.g., any one, any combination, or all of: the type of proppants used; the sequence of proppants used; the concentrations of proppants used; the timing of proppants used; or the like) in another subsurface, such as in an adjacent field.

In one or some embodiments, the flow diagram 300 may be used in a single iteration. Alternatively, the flow diagram 300 may be used iteratively, generating one or more outputs, which may in turn be used as feedback to step 320 for a next iteration.

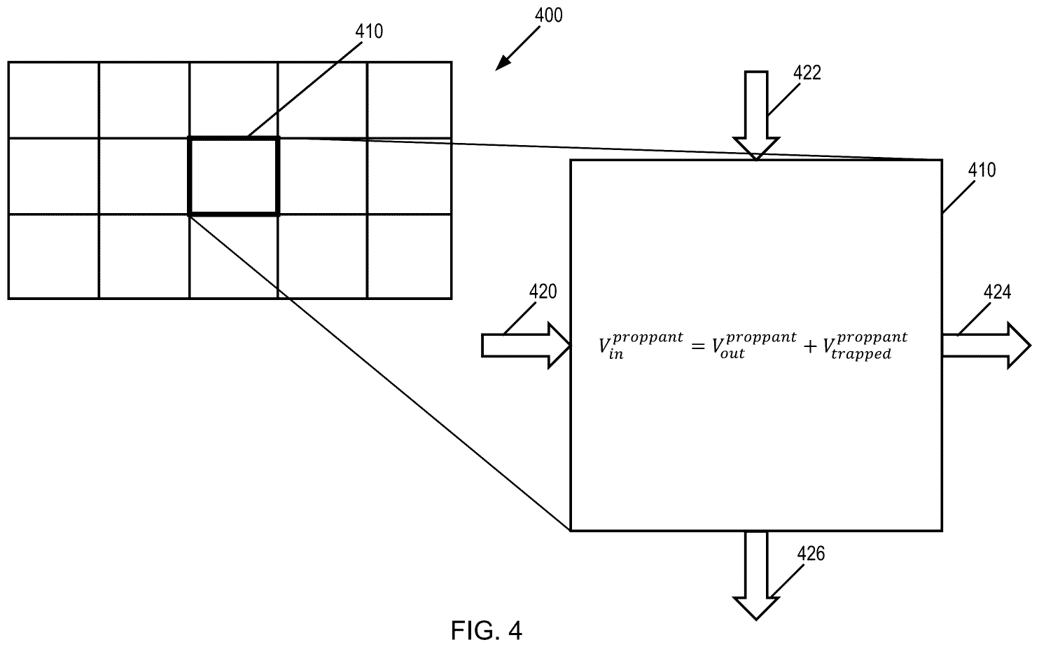

FIG. 4 is an illustration of a grid 400 of the surface of a fracture, which may be discretized into various sections, such as section 410, of the grid 400. With a respective section 410, associated calculations related to proppant in the section 410 of the grid 400 may be calculated. As shown, there are various inputs/outputs to the section 410 of the grid, designated by arrows 420, 422, 424, 426.

As discussed above, proppant injected during fracturing may be trapped along the surface of the fracture. This may occur gradually during and after the fracturing process. The trapping process may be integrated with proppant transport as the amount of proppant trapped affects the amount available to be transported and vice versa. Examples of integration include: no trapping resulting in all of the proppant settling over time because of gravitational settling; or low trapping results in a larger propped area compared to high trapping.

In practice, a simulator may solve a system of equations in the fracture, with proppant trapping being one part of the simulation. Each section (or cell) in the grid may be analyzed for a conservation of mass balance, with the amount of proppant into the section (Vᵢₙ^{proppant}) being equal to the amount of proppant that goes out of the section (Vₒᵤₜ^{proppant}) and the amount of proppant that is trapped within a cell (V_{trapped}^{proppant}). This calculation may be performed at each section/cell within the grid and at each time stamp, and may be performed iteratively. As such, the volume-based proppant trapping model is focused on the volume of proppant that is trapped (rather than the mass of proppant trapped). Further, the trapping process may be tightly integrated with the proppant transport process, with the amount of proppant trapped being affected by the amount of proppant available, various coefficients (such as shown in Equation (3)), etc. Moreover, as discussed above, one or more parameters of the volume-based proppant trapping model may be spatially dependent, such as V_{tot,max}(x, y, z) and V_{i,trap}. Thus, the amount of proppant trapped may vary depending on location in the grid. In this way, the volume-based proppant trapping model may illustrate how the proppant is moving at the fracture. At the end of a respective time step, the volume-based proppant trapping model may thus provide an understanding of the proppant transport process (and the volume of proppant that is trapped).

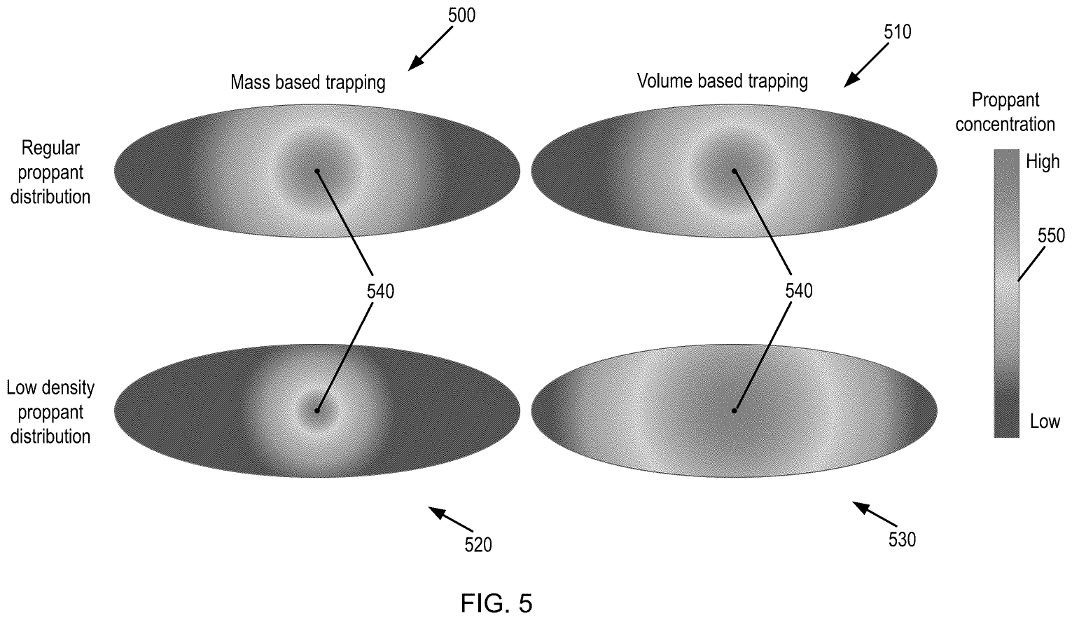

FIG. 5 illustrates schematics 500, 510, 520, 530 of differences in the mass-based proppant trapping approach versus the volume-based proppant trapping approach for a regular proppant density distribution and a lower-proppant density distribution for wellbore 540. In particular, schematics 500, 510, 520, 530 illustrate the determined proppant distribution in the fracture for the same total volume of proppant injected via the mass-based trapping methodology and the volume-based trapping methodology. As shown, for a regular proppant distribution, the schematic 500 for mass-based trapping methodology is similar to the schematic 520 for volume-based trapping methodology. In contrast, for a low density proppant distribution (e.g., lower density than the regular proppant), the schematic 510 for mass-based trapping methodology is dissimilar to the schematic 530 for volume-based trapping methodology.

As illustrated in FIG. 5, more lower density proppant is shown in schematic 510 as trapped near the wellbore when using the mass-based trapping methodology. See legend 550. In contrast, the volume-based trapping methodology shown in schematic 530 may allow lower density proppant to travel further with the fluid and reduce the trapped volume compared to the mass-based trapping methodology. Thus, in using the volume-based trapping methodology shown in schematic 530, higher concentrations of proppant are illustrated further away from the wellbore 540 because the proppant is lighter and may be carried further away from the wellbore 540. In fracking, it may be desirable to maintain a greater opening. According to the schematic 530 using the volume-based proppant trapping methodology, it is shown that using lower density proppant may be better for maintaining the greater opening. It is noted that this is the opposite of the depiction shown in schematic 510, which is using the mass-based proppant methodology and indicates that using the low density proppant is considered undesirable for maintaining the greater opening.

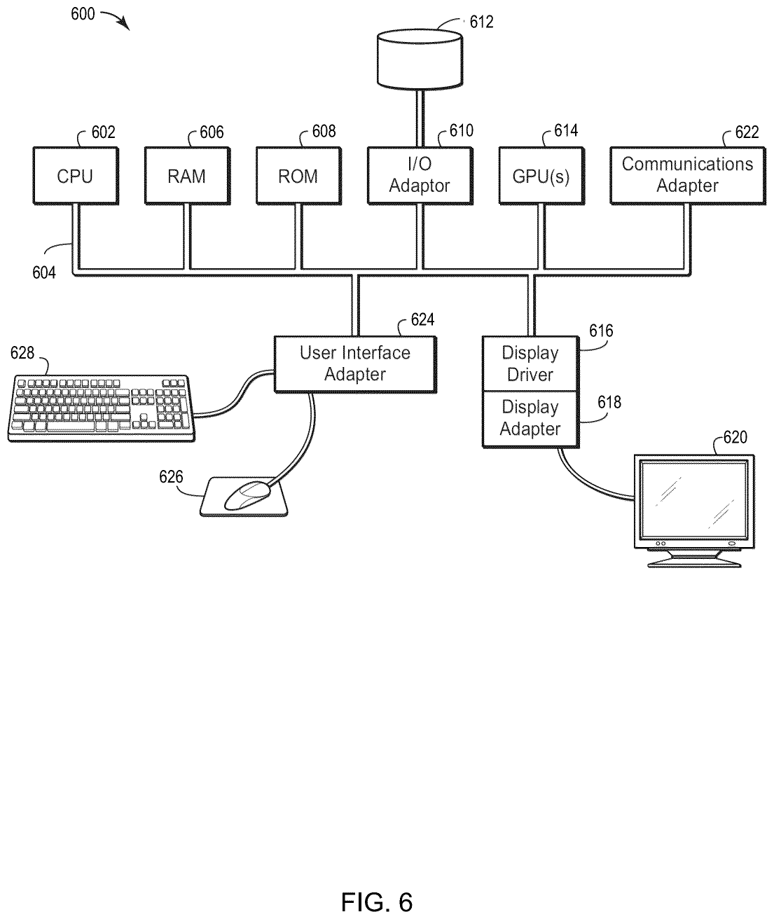

In all practical applications, the present technological advancement must be used in conjunction with a computer, programmed in accordance with the disclosures herein. For example, FIG. 6 is a diagram of an exemplary computer system 600 that may be utilized to implement methods described herein. A central processing unit (CPU) 602 is coupled to system bus 604. The CPU 602 may be any general-purpose CPU, although other types of architectures of CPU 602 (or other components of exemplary computer system 600) may be used as long as CPU 602 (and other components of computer system 600) supports the operations as described herein. Those of ordinary skill in the art will appreciate that, while only a single CPU 602 is shown in FIG. 6, additional CPUs may be present. Moreover, the computer system 600 may comprise a networked, multi-processor computer system that may include a hybrid parallel CPU/GPU system. The CPU 602 may execute the various logical instructions according to various teachings disclosed herein. For example, the CPU 602 may execute machine-level instructions for performing processing according to the operational flow described.

The computer system 600 may also include computer components such as non-transitory, computer-readable media. Examples of computer-readable media include computer-readable non-transitory storage media, such as a random access memory (RAM) 606, which may be SRAM, DRAM, SDRAM, or the like. The computer system 600 may also include additional non-transitory, computer-readable storage media such as a read-only memory (ROM) 608, which may be PROM, EPROM, EEPROM, or the like. RAM 606 and ROM 608 hold user and system data and programs, as is known in the art. The computer system 600 may also include an input/output (I/O) adapter 610, a graphics processing unit (GPU) 614, a communications adapter 622, a user interface adapter 624, a display driver 616, and a display adapter 618.

The I/O adapter 610 may connect additional non-transitory, computer-readable media such as storage device(s) 612, including, for example, a hard drive, a compact disc (CD) drive, a floppy disk drive, a tape drive, and the like to computer system 600. The storage device(s) may be used when RAM 606 is insufficient for the memory requirements associated with storing data for operations of the present techniques. The data storage of the computer system 600 may be used for storing information and/or other data used or generated as disclosed herein. For example, storage device(s) 612 may be used to store configuration information or additional plug-ins in accordance with the present techniques. Further, user interface adapter 624 couples user input devices, such as a keyboard 628, a pointing device 626 and/or output devices to the computer system 600. The display adapter 618 is driven by the CPU 602 to control the display on a display device 620 to, for example, present information to the user such as subsurface images generated according to methods described herein.

The architecture of computer system 600 may be varied as desired. For example, any suitable processor-based device may be used, including without limitation personal computers, laptop computers, computer workstations, and multi-processor servers. Moreover, the present technological advancement may be implemented on application specific integrated circuits (ASICs) or very large scale integrated (VLSI) circuits. In fact, persons of ordinary skill in the art may use any number of suitable hardware structures capable of executing logical operations according to the present technological advancement. The term “processing circuit” encompasses a hardware processor (such as those found in the hardware devices noted above), ASICs, and VLSI circuits. Input data to the computer system 600 may include various plug-ins and library files. Input data may additionally include configuration information.

Preferably, the computer is a high-performance computer (HPC), known to those skilled in the art. Such high-performance computers typically involve clusters of nodes, each node having multiple CPU's and computer memory that allow parallel computation. The models may be visualized and edited using any interactive visualization programs and associated hardware, such as monitors and projectors. The architecture of system may vary and may be composed of any number of suitable hardware structures capable of executing logical operations and displaying the output according to the present technological advancement. Those of ordinary skill in the art are aware of suitable supercomputers available from Cray or IBM or other cloud computing based vendors such as Microsoft, Amazon.

The above-described techniques, and/or systems implementing such techniques, can further include hydrocarbon management based at least in part upon the above techniques, including using the one or more generated geological models in one or more aspects of hydrocarbon management. For instance, methods according to various embodiments may include managing hydrocarbons based at least in part upon the one or more generated geological models and data representations (e.g., seismic images, feature probability maps, feature objects, etc.) constructed according to the above-described methods. In particular, such methods may include drilling a well, and/or causing a well to be drilled, based at least in part upon the one or more generated geological models and data representations discussed herein (e.g., such that the well is located based at least in part upon a location determined from the models and/or data representations, which location may optionally be informed by other inputs, data, and/or analyses, as well) and further prospecting for and/or producing hydrocarbons using the well.

It is intended that the foregoing detailed description be understood as an illustration of selected forms that the invention can take and not as a definition of the invention. It is only the following claims, including all equivalents which are intended to define the scope of the claimed invention. Further, it should be noted that any aspect of any of the preferred embodiments described herein may be used alone or in combination with one another. Finally, persons skilled in the art will readily recognize that in preferred implementation, some or all of the steps in the disclosed method are performed using a computer so that the methodology is computer implemented. In such cases, the resulting physical properties model may be downloaded or saved to computer storage.

The following example embodiments of the invention are also disclosed.

### EMBODIMENT 1

A computer-implemented method for using a volume-based proppant trapping model, the method comprising:
accessing one or more inputs;
inputting the one or more inputs into the volume-based proppant trapping model in order to generate one or more outputs indicative of proppant trapping in or at a fracture surface; and
outputting the one or more outputs or using the one or more outputs in order to control at least one aspect fracking in a subsurface.

### EMBODIMENT 2

The method of embodiment 1:
wherein the one or more outputs are used to modify at least one aspect of the fracking.

### EMBODIMENT 3

The method of embodiments 1 or 2:
wherein the one or more inputs comprises any one, any combination, or all of a maximum allowed trapped volume of all proppant types per unit fracture surface area, a rate of proppant trapping, or a volume of proppant passed through the fracture surface.

### EMBODIMENT 4

The method of embodiments 1-3:
wherein any one, any combination, or all of the maximum allowed trapped volume of all proppant types per unit fracture surface area, the rate of proppant trapping, or the volume of proppant passed along the fracture surface are invariant.

### EMBODIMENT 5

The method of embodiments 1-4:
wherein any one, any combination, or all of the maximum allowed trapped volume of all proppant types per unit fracture surface area, the rate of proppant trapping, or the volume of proppant passed along the fracture surface are variant.

### EMBODIMENT 6

The method of embodiments 1-5:
wherein any one, any combination, or all of the maximum allowed trapped volume of all proppant types per unit fracture surface area, the rate of proppant trapping, or the volume of proppant passed along the fracture surface is dependent on one or both of rock properties in the subsurface or type of proppant injected.

### EMBODIMENT 7

The method of embodiments 1-6:
wherein any one, any combination, or all of the maximum allowed trapped volume of all proppant types per unit fracture surface area, the rate of proppant trapping, or the volume of proppant passed along the fracture surface is spatially dependent.

### EMBODIMENT 8

The method of embodiments 1-7:
wherein any one, any combination, or all of the maximum allowed trapped volume of all proppant types per unit fracture surface area, the rate of proppant trapping, or the volume of proppant passed along the fracture surface is dependent on a sequence in which proppants are introduced.

### EMBODIMENT 9

The method of embodiments 1-8:
wherein any one, any combination, or all of the maximum allowed trapped volume of all proppant types per unit fracture surface area, the rate of proppant trapping, or the volume of proppant passed along the fracture surface is time dependent.

### EMBODIMENT 10

The method of embodiments 1-9:
wherein the volume-based proppant trapping model is used to determine which at least one proppant, from a set of potential proppants, to select for the fracking in the subsurface.

### EMBODIMENT 11

The method of embodiments 1-10:
wherein the volume-based proppant trapping model is used to determine which plurality of proppants, from a set of potential proppants, to select for the fracking in the subsurface.

### EMBODIMENT 12

The method of embodiments 1-11:
wherein the volume-based proppant trapping model is used to determine concentrations for the plurality of proppants selected for the fracking in the subsurface.

### EMBODIMENT 13

The method of embodiments 1-12:
wherein the volume-based proppant trapping model is used to determine a sequence of using the plurality of proppants for the fracking in the subsurface.

### EMBODIMENT 14

The method of embodiments 1-13:
wherein the volume-based proppant trapping model is used to determine which proppant, from a set of potential proppants, to select for the fracking in the subsurface, the set of potential proppants including proppants of different densities.

### EMBODIMENT 15

The method of embodiments 1-14:
wherein the volume-based proppant trapping model is used to optimize a proppant schedule by maximizing well productivity while minimizing volume of proppant injected.

### EMBODIMENT 16

The method of embodiments 1-15:
wherein one or both of the maximum allowed trapped volume of all proppant types per unit fracture surface area or the rate of proppant trapping are variable depending on at least one aspect of operation.

### EMBODIMENT 17

The method of embodiments 1-16:
wherein the at least one aspect of operation comprises at least one of: fluid rheology; fluid flow field; or operational parameters.

### EMBODIMENT 18

The method of embodiments 1-17:
wherein the maximum allowed trapped volume V_{tot,max} of all proppant types per unit fracture surface area across the fracture surface; and
wherein the volume-based proppant trapping model is based on:

$$\frac{{dV}_{i , trap}}{d t} = {K}_{trap} ( {V}_{i} - {V}_{i , trap} )$$

where V_{i,trap} is volume of trapped proppant for proppant type i per unit fracture surface area;
where Kₜᵣₐₚ is a constant rate of proppant trapping; and
where Vᵢ is volume of proppant type i per unit fracture surface area.

### EMBODIMENT 19

The method of embodiments 1-18:
wherein the maximum allowed trapped volume V_{i,tot,max} of different proppant types per unit fracture surface area across the fracture surface; and
wherein the volume-based proppant trapping model is based on:

$$\frac{{dV}_{i , trap}}{d t} = {K}_{trap} ( {V}_{i} - {V}_{i , trap} )$$

where V_{i,trap} is volume of trapped proppant for proppant type i per unit fracture surface area;
where Kₜᵣₐₚ is a constant rate of proppant trapping; and
where Vᵢ is volume of proppant type i per unit fracture surface area.

### EMBODIMENT 20

The method of embodiments 1-19:
wherein the maximum allowed trapped volume of all proppant types per unit fracture surface area is spatially variable across the fracture surface; and
wherein the volume-based proppant trapping model is based on:

$$\frac{{dV}_{i , trap}}{d t} = {K}_{trap} [ x , y , z ] ( {V}_{i} - {V}_{i , trap} )$$

where V_{i,trap} is volume of trapped proppant for proppant type i per unit fracture surface area;
where Kₜᵣₐₚ[x, y, z] is a spatially variable rate of proppant trapping; and
where Vᵢ is volume of proppant type i per unit fracture surface area.

### EMBODIMENT 21

The method of embodiments 1-20:
wherein the volume-based proppant trapping model is based on dividing a fracture surface into cells of a grid and simulating proppant trapping in each of the cells in the grid by determining a volume of proppant into a respective cell, a volume of proppant exiting the respective cell and a volume of proppant trapped in the respective cell.

### EMBODIMENT 22

The method of embodiments 1-21:
wherein analysis with regard to the volume-based proppant trapping model is at least partly spatially dependent.

### EMBODIMENT 23

The method of embodiments 1-22:
wherein generating the one or more outputs indicative of the proppant trapping in or at the fracture surface is dependent on any one, any combination, or all of a spatially dependent maximum allowed trapped volume of proppant along the fracture surface, a spatially dependent rate of trapping, or a spatially dependent volume of proppant passed along the fracture surface.

### EMBODIMENT 24

The method of embodiments 1-23:
wherein the any one, any combination, or all of the maximum allowed trapped volume of all proppant types per unit fracture surface area, the rate of proppant trapping, or the volume of proppant passed along the fracture surface is randomized.

### EMBODIMENT 25

The method of embodiments 1-24:
wherein the one or more outputs indicative of proppant trapping in or at the fracture surface is indicative of fracture conductivity along the fracture surface; and
wherein the fracture conductivity is used for controlling or modifying fracture treatments in the subsurface.

### EMBODIMENT 26

A system comprising:
a processor; and
a non-transitory machine-readable medium comprising instructions that, when executed by the processor, cause a computing system to perform a method according to any of embodiments 1-25.

### EMBODIMENT 27

A non-transitory machine-readable medium comprising instructions that, when executed by a processor, cause a computing system to perform a method according to any of embodiments 1-26.

What is claimed is:

1. A computer-implemented method for using a volume-based proppant trapping model, the method comprising:
accessing one or more inputs;
inputting the one or more inputs into the volume-based proppant trapping model in order to generate one or more outputs indicative of proppant trapping in or at a fracture surface; and
outputting the one or more outputs or using the one or more outputs in order to control at least one aspect fracking in a subsurface.

2. The method of claim 1, wherein the one or more outputs are used to modify at least one aspect of the fracking.

3. The method of claim 1, wherein the one or more inputs comprises any one, any combination, or all of a maximum allowed trapped volume of all proppant types per unit fracture surface area, a rate of proppant trapping, or a volume of proppant passed along the fracture surface.

4. The method of claim 3, wherein any one, any combination, or all of the maximum allowed trapped volume of all proppant types per unit fracture surface area, the rate of proppant trapping, or the volume of proppant passed along the fracture surface are invariant.

5. The method of claim 3, wherein any one, any combination, or all of the maximum allowed trapped volume of all proppant types per unit fracture surface area, the rate of proppant trapping, or the volume of proppant passed along the fracture surface are variant.

6. The method of claim 3, wherein any one, any combination, or all of the maximum allowed trapped volume of all proppant types per unit fracture surface area, the rate of proppant trapping, or the volume of proppant passed along the fracture surface is dependent on one or both of rock properties in the subsurface or type of proppant injected.

7. The method of claim 3, wherein any one, any combination, or all of the maximum allowed trapped volume of all proppant types per unit fracture surface area, the rate of proppant trapping, or the volume of proppant passed along the fracture surface is spatially dependent.

8. The method of claim 3, wherein any one, any combination, or all of the maximum allowed trapped volume of all proppant types per unit fracture surface area, the rate of proppant trapping, or the volume of proppant passed along the fracture surface is dependent on a sequence in which proppants are introduced.

9. The method of claim 3, wherein any one, any combination, or all of the maximum allowed trapped volume of all proppant types per unit fracture surface area, the rate of proppant trapping, or the volume of proppant passed along the fracture surface is time dependent.

10. The method of claim 3, wherein the volume-based proppant trapping model is used to determine which at least one proppant, from a set of potential proppants, to select for the fracking in the subsurface.

11. The method of claim 10, wherein the volume-based proppant trapping model is used to determine which plurality of proppants, from a set of potential proppants, to select for the fracking in the subsurface.

12. The method of claim 11, wherein the volume-based proppant trapping model is used to determine concentrations for the plurality of proppants selected for the fracking in the subsurface.

13. The method of claim 11, wherein the volume-based proppant trapping model is used to determine a sequence of using the plurality of proppants for the fracking in the subsurface.

14. The method of claim 3, wherein the volume-based proppant trapping model is used to determine which proppant, from a set of potential proppants, to select for the fracking in the subsurface, the set of potential proppants including proppants of different densities.

15. The method of claim 3, wherein the volume-based proppant trapping model is used to optimize a proppant schedule by maximizing well productivity while minimizing volume of proppant injected.

16. The method of claim 3, wherein one or both of the maximum allowed trapped volume of all proppant types per unit fracture surface area or the rate of proppant trapping are variable depending on at least one aspect of operation.

17. The method of claim 16, wherein the at least one aspect of operation comprises at least one of: fluid rheology; fluid flow field; or operational parameters.

18. The method of claim 3, wherein the maximum allowed trapped volume V_{tot,max} of all proppant types per unit fracture surface area across the fracture surface; and
wherein the volume-based proppant trapping model is based on:
$$\frac{{dV}_{i , trap}}{d t} = {K}_{trap} ( {V}_{i} - {V}_{i , trap} )$$
where V_{i,trap} is volume of trapped proppant for proppant type i per unit fracture surface area;
where Kₜᵣₐₚ is a constant rate of proppant trapping; and
where Vᵢ is volume of proppant type i per unit fracture surface area.

19. The method of claim 3, wherein the maximum allowed trapped volume V_{i,tot,max} of different proppant types per unit fracture surface area across the fracture surface; and
wherein the volume-based proppant trapping model is based on:
$$\frac{{dV}_{i , trap}}{d t} = {K}_{trap} ( {V}_{i} - {V}_{i , trap} )$$
where V_{i,trap} is volume of trapped proppant for proppant type i per unit fracture surface area;
where Kₜᵣₐₚ is a constant rate of proppant trapping; and
where Vᵢ is volume of proppant type i per unit fracture surface area.

20. The method of claim 3, wherein the maximum allowed trapped volume of all proppant types per unit fracture surface area is spatially variable across the fracture surface; and
wherein the volume-based proppant trapping model is based on:
$$\frac{{dV}_{i , trap}}{d t} = {K}_{trap} [ x , y , z ] ( {V}_{i} - {V}_{i , trap} )$$
where V_{i,trap} is volume of trapped proppant for proppant type i per unit fracture surface area;
where Kₜᵣₐₚ[x, y, z] is a spatially variable rate of proppant trapping; and
where Vᵢ is volume of proppant type i per unit fracture surface area.

21. The method of claim 1, wherein the volume-based proppant trapping model is based on dividing a fracture surface into cells of a grid and simulating proppant trapping in each of the cells in the grid by determining a volume of proppant into a respective cell, a volume of proppant exiting the respective cell and a volume of proppant trapped in the respective cell.

22. The method of claim 21, wherein analysis with regard to the volume-based proppant trapping model is at least partly spatially dependent.

23. The method of claim 22, wherein generating the one or more outputs indicative of the proppant trapping in or at the fracture surface is dependent on any one, any combination, or all of a spatially dependent maximum allowed trapped volume of proppant along the fracture surface, a spatially dependent rate of trapping, or a spatially dependent volume of proppant passed along the fracture surface.

24. The method of claim 23, wherein the any one, any combination, or all of the maximum allowed trapped volume of all proppant types per unit fracture surface area, the rate of proppant trapping, or the volume of proppant passed along the fracture surface is randomized.

25. The method of claim 1, wherein the one or more outputs indicative of proppant trapping in or at the fracture surface is indicative of fracture conductivity along the fracture surface; and
wherein the fracture conductivity is used for controlling or modifying fracture treatments in the subsurface.
